(19) United States
(12) Patent Application Publication
(10) Pub. No.: US 2024/0145632 A1
(43) Pub. Date: May 2, 2024

(54) MICRO LIGHT EMITTING DEVICE AND MICRO LIGHT EMITTING APPARATUS USING THE SAME

(71) Applicant: XIAMEN SAN'AN OPTOELECTRONICS CO., LTD., Xiamen (CN)

(72) Inventors: Ming-Chun TSENG, Xiamen (CN); Shaohua HUANG, Xiamen (CN); Hongwei WANG, Xiamen (CN); Kang-Wei PENG, Xiamen (CN); Su-Hui LIN, Xiamen (CN); Xiaomeng LI, Xiamen (CN); Chi-Ming TSAI, Xiamen (CN); Chung-Ying CHANG, Xiamen (CN)

(21) Appl. No.: 18/492,427

(22) Filed: Oct. 23, 2023

(30) Foreign Application Priority Data
Oct. 28, 2022 (CN) 202211338493.0

(51) Int. Cl. H01L 33/38; H01L 25/075; H01L 33/22; H01L 33/40; H01L 33/42

(52) U.S. Cl. CPC H01L 33/38; H01L 25/0753; H01L 33/22; H01L 33/405; H01L 33/42; H01L 33/30

(57) ABSTRACT

A micro light emitting device includes an epitaxial structure, a conductive layer, and a first insulating layer. The epitaxial structure has a first surface and a second surface opposite to the first surface, and includes a first semiconductor layer, an active layer and a second semiconductor layer that are arranged in such order in a direction from the first surface to the second surface. The conductive layer is formed on a surface of the first semiconductor layer away from the active layer. The first insulating layer is formed on the surface of the first semiconductor layer away from the active layer, and exposes at least a part of the conductive layer.

### CROSS-REFERENCE TO RELATED APPLICATION

This application claims priority to Chinese Invention Patent Application No. 202211338493.0, filed on Oct. 28, 2022, and incorporated by reference herein in its entirety.

### FIELD

The disclosure relates to a semiconductor light emitting device, and more particularly to a micro light emitting device and a micro light emitting apparatus.

### BACKGROUND

In recent years, light emitting diodes (LEDs) have been widely used in fields such as illumination, and have replaced conventional light sources. With evolution of technology, micro light emitting diodes (micro LEDs) have acquired advantages such as low power consumption, high brightness, ultra-high resolution, ultra-high color saturation, fast response time, low energy consumption, long lifespan, etc., and are gradually being used as light emitting devices in displays.

The power consumption of a micro LED display is about 10% of a liquid crystal display (LCD) or 50% of an organic light emitting diode (OLED) display. In addition, compared to self-emissive OLED displays, which are also, micro LED displays boast a 30-fold increase in brightness and can achieve a resolution of up to 1500 PPI (Pixels Per Inch).

In an LED, when electrons recombine with holes, the energy generated due to the recombination is released in the form of photons, thereby emitting light. This is known as radiative recombination. A passive-matrix micro LED display has a small size, and thus, a thickness of an epitaxial structure contained in the passive-matrix micro LED display is relatively thin and each pixel is small, can easily have reduced device characteristics such as voltage rise or leakage current level rise due to non-radiative recombination. Furthermore, ohmic contact in the epitaxial structure does not allow direct application of a setup method used in a conventional LED with typical size. In micro LED displays, how to control current flow and maintain efficiency and uniformity of the micro LEDs is one of hot research topics in the industry.

Therefore, how to effectively solve the voltage rise problem caused by size effect in a small size design so as to control the current uniformity and stabilize voltage in the micro LEDs is a crucial technical challenge for a skilled artisan.

### SUMMARY

Therefore, an object of the disclosure is to provide a micro light emitting device and a micro light emitting apparatus that can alleviate at least one of the drawbacks of the prior art.

According to the disclosure, the micro light emitting device includes an epitaxial structure, a conductive layer, and a first insulating layer. The epitaxial structure has a first surface and a second surface opposite to the first surface, and includes a first semiconductor layer, an active layer and a second semiconductor layer that are arranged in such order in a direction from the first surface to the second surface. The conductive layer is formed on a surface of the first semiconductor layer away from the active layer. The first insulating layer is formed on the surface of the first semiconductor layer away from the active layer, and exposes at least a part of the conductive layer.

According to another aspect of the disclosure, the micro light emitting apparatus includes at least two of the aforesaid micro light emitting devices. The at least two micro light emitting devices are electrically connected to each other, and a distance between two adjacent ones of the at least two micro light emitting devices is 2 μm.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a cross-sectional schematic view illustrating a first embodiment of a micro light emitting device according to the disclosure.

FIG. 2 is a schematic bottom view of the first embodiment of the micro light emitting device shown in FIG. 1.

FIG. 3 is a schematic top view of the first embodiment of the micro light emitting device shown in FIG. 1.

FIG. 4 is a schematic top view illustrating a distribution manner of second electrodes of an embodiment of a micro light emitting device.

FIG. 5 is a cross-sectional schematic view illustrating a second embodiment of a micro light emitting device according to the disclosure.

FIG. 6 is a cross-sectional schematic view illustrating a third embodiment of a micro light emitting device according to the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

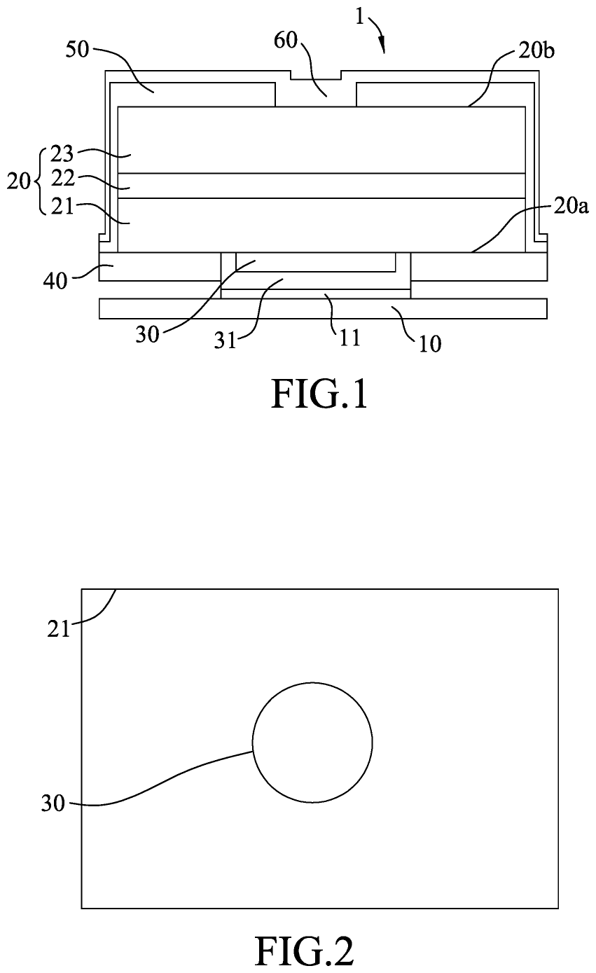

FIG. 1 is a cross-sectional schematic view illustrating a first embodiment of a micro light emitting device 1 according to the disclosure. The first embodiment of the micro light emitting device 1 includes an epitaxial structure 20, a conductive layer 30, and a first insulating layer 40. The epitaxial structure 20 has a first surface 20a and a second surface 20b opposite to the first surface 20a, and includes a first semiconductor layer 21, an active layer 22 and a second semiconductor layer 23 that are arranged in such order in a direction from the first surface 20a to the second surface 20b. The conductive layer 30 is formed on a surface of the first semiconductor layer 21 away from the active layer 22. The first insulating layer 40 is formed on the surface of the first semiconductor layer 21 away from the active layer 22, and exposes at least a part of the conductive layer 30.

The epitaxial structure 20 may be formed on a substrate by metal organic chemical vapor deposition (MOCVD), molecular beam epitaxy (MBE), hydride vapor phase epitaxy (HYPE), physical vapor deposition (PVD), or ion plating method, etc. According to different functions and applications of the micro light emitting device 1, the substrate may be a substrate for temporary growth. After the epitaxial structure 20 is well formed, the epitaxial structure 20 is transferred onto another substrate for subsequent processing.

The epitaxial structure 20 may emit light with a specific central emission wavelength, including, but not limited to, blue light, green light, red light, violet light, or ultraviolet light. The first semiconductor layer 21 has a conductivity type that is opposite to that of the second semiconductor layer 23.

In an exemplary embodiment, the first semiconductor layer 21 is a P-type semiconductor layer and the second semiconductor layer 23 is an N-type semiconductor layer, but the disclosure is not limited thereto. In certain embodiments, the first semiconductor layer 21 may be an N-type semiconductor layer and the second semiconductor layer 23 may be a P-type semiconductor layer.

In an exemplary embodiment, the first semiconductor layer 21 of the epitaxial structure 20 is a P-type semiconductor layer, which provides holes to the active layer 22 when biased with an electric current. In some embodiments, the first semiconductor layer 21 includes a P-type doped nitride layer, a P-type doped phosphide layer, or a P-type doped arsenide layer. The P-type doped nitride layer, the P-type doped phosphide layer, or the P-type doped arsenide layer includes one or more P-type dopants chosen from group II elements. The P-type dopant may be magnesium (Mg), zinc (Zn), beryllium (Be), or combinations thereof. The first semiconductor layer 21 may be a single-layer structure or a multi-layer structure having different compositions.

The active layer 22 may be a quantum well structure. The active layer 22 may be a single quantum well structure, or a multiple quantum well structure. In certain embodiments, the active layer 22 has a multiple quantum well structure, which includes a plurality of quantum well layers and a plurality of quantum barrier layers that are alternately stacked. In some embodiments, the active layer 22 may include a multiple quantum well structure, e.g., GaN/AlGaN, InAlGaN/InAlGaN, InGaN/AlGaN, GaInP/AIGaInP, GaInP/AlInP, or InGaAs/AlInGaAs, etc. In order to improve luminous efficiency of the active layer 22, thickness of the quantum well layer, the number of layers of paired quantum well layers and quantum barrier layers, and/or other features in the active layer 22 may be adjusted.

In an exemplary embodiment, the second semiconductor layer 23 of the epitaxial structure 20 is an N-type semiconductor layer, which provides electrons to the active layer 22 when biased with an electric current. In some embodiments, the second semiconductor layer 23 includes an N-type doped nitride layer, an N-type doped phosphide layer, or an N-type doped arsenide layer. The N-type doped nitride layer includes one or more N-type dopants chosen from the group IV elements. The N-type dopant may be silicon (Si), germanium (Ge), tin (Sn), or combinations thereof. In this embodiment, the second surface 20b of the epitaxial structure 20 is a surface of the second semiconductor layer 23 away from the active layer 22. A configuration of the epitaxial structure 20 is not limited thereto, and an alternative configuration may be adopted based on actual demands for the micro light emitting device 1.

In this embodiment, the first surface 20a of the epitaxial structure 20 is the surface of the first semiconductor layer 21 away from the active layer 22. The conductive layer 30 is formed on the surface of the first semiconductor layer 21 away from the active layer 22. Thus, in this embodiment as shown in FIG. 1, the conductive layer 30 is located on the first surface 20a of the epitaxial structure 20. Specifically, the conductive layer 30 is formed on at least a part of the surface of the first semiconductor layer 21 (serving as the P-type semiconductor layer in FIG. 1) away from the active layer 22, so as to perform current spreading on the surface of the first semiconductor layer 21 to ensure uniformity of current spreading in the first semiconductor layer 21.

In certain embodiments, the conductive layer 30 has a thickness ranging from 50 Å to 1000 Å. The conductive layer 30 may be a metal conductive layer and may contain a metal material, e.g., titanium (Ti), palladium (Pd), gold (Au), chromium (Cr), nickel (Ni), platinum (Pt), or combinations thereof. By virtue of controlling the thickness of the conductive layer 30, improved current spreading and a reduction in light absorption can be achieved. Furthermore, the conductive layer 30 enables the first semiconductor layer 21 to have good electrical conductivity and good current spreading ability, while minimally affecting light absorption, thereby allowing the micro light emitting device 1 to have excellent light emitting properties.

In some embodiments, the conductive layer 30 may include an oxide material with high transparency, high electrical conductivity, and low contact resistance, such as indium tin oxide (ITO), indium zinc oxide (IZO), zinc oxide (ZnO), cadmium tin oxide (CTO), indium oxide (InO), In-doped zinc oxide (ZnO), aluminum (Al)-doped zinc oxide (ZnO), gallium (Ga)-doped zinc oxide (ZnO), or combinations thereof to enhance current spreading effect of the conductive layer 30. In some embodiments, the conductive layer 30 may contain the metal material and the oxide material.

In certain embodiments, the conductive layer 30 may include a reflective metal such as aluminum (Al), silver (Ag), etc., to enhance light reflection performance of the conductive layer 30. With the reflective metal, the conductive layer 30 gains reflector-like functionality, which enhances luminous brightness of the micro light emitting device 1. In an exemplary embodiment as shown in FIG. 1, the reflective metal of the conductive layer 30 is silver (Ag). Based on type and design requirements of the conductive layer 30, an area of the conductive layer 30 containing the reflective metal may be adjusted, so as to adjust a size of the area having reflector-like functionality, thereby adjusting the luminous efficiency of the micro light emitting device 1.

In certain embodiments, the conductive layer 30 may also serve as an ohmic contact layer of the first semiconductor layer 21, so as to ensure that the micro light emitting device 1 has excellent electrical property. In some embodiments, the micro light emitting device 1 may further include an electrode pad 31. The conductive layer 30 and the electrode pad 31 may serve as an electrode corresponding to the first semiconductor layer 21. In comparison with a conventional composite electrode having ITO and metal, a process for forming the conductive layer 30 and the electrode pad 31 of this disclosure is relatively simplified, and is cost effective, and the micro light emitting device 1 has a more stable low forward voltage (VF). In the exemplary embodiment as shown in FIG. 1, the conductive layer 30 and the electrode pad 31 are separately formed. The electrode pad 31 is formed on the conductive layer 30 and covers at least a part of the conductive layer 30.

In order to facilitate the conductive layer 30 in achieving a continuous and stable photoelectric performance on the first semiconductor layer 21, the first insulating layer 40 may be formed on the conductive layer 30 to partially cover and protect the conductive layer 30. As shown in FIG. 1, the first insulating layer 40 indirectly covers a part of the conductive layer 30 and directly covers the surface of the first semiconductor layer 21 away from the active layer 22. In certain embodiments, the first insulating layer 40 contains silicon dioxide (SiO₂), silicon nitride (Si₃N₄), titanium dioxide (TiO₂), titanium (III) oxide (Ti₂O₃), trititanium pentoxide (Ti₃O₅), tantalum pentoxide (Ta₂O₅), zirconium dioxide (ZrO₂), or combinations thereof. In certain embodiments, the electrode pad 31 is formed on the conductive layer 30 and covers at least a part of the conductive layer 30. The first insulating layer 40 is formed on the surface of the first semiconductor layer 21 away from the active layer 22, and exposes a part of the electrode pad 31.

In some embodiments, as shown in FIG. 1, the micro light emitting device 1 may further include a second insulating layer 50 and a transparent conductive layer 60. The second insulating layer 50 is formed on the surface of the second semiconductor layer 23 away from the active layer 22, and exposes a part of the second semiconductor layer 23. In FIG. 1, the second surface 20b of the epitaxial structure 20 is the surface of the second semiconductor layer 23 away from the active layer 22. The second insulating layer 50 is formed on the second surface 20b of the epitaxial structure 20. The second insulating layer 50 has a thickness ranging from 0.1 Å to 4000 Å. The second insulating layer 50 may cover a part of the second semiconductor layer 23 and sidewalls of the first semiconductor layer 21, the active layer 22, and the second semiconductor layer 23 of the epitaxial structure 20 to protect the sidewalls (non-light emitting region) of the epitaxial structure 20.

The transparent conductive layer 60 is formed on the second insulating layer 50, and is electrically connected to the second semiconductor layer 23. When a plurality of micro light emitting devices 1 are disposed side by side and connected to each other, the transparent conductive layer 60 may serve as a common electrode connected between the micro light emitting devices 1. As shown in FIG. 1, the transparent conductive layer 60 may be formed with a recess recessed from an upper surface of the transparent conductive layer 60. The transparent conductive layer 60 is made of an oxide material with high transparency, high electrical conductivity, and low contact resistance, such as ITO, IZO, ZnO, CTO, InO, In-doped ZnO, Al-doped ZnO, Ga-doped ZnO, or combinations thereof. The transparent conductive layer 60 may also contain Ag, Au, Cr, copper (Cu), Pt, Sn, Ni, Ti, Al, or combinations thereof. The transparent conductive layer 60 may have a single-layer structure or a laminated structure. The transparent conductive layer 60 has a thickness ranging from 0.1 Å to 1100 Å. In a non-high temperature fusion process, the transparent conductive layer 60 disposed on the second insulating layer 50 has a sufficient thickness, so that the surface of the second semiconductor layer 23 away from the active layer 22 not only exhibits an excellent electrical conductivity but also has high transparency under visible light, thereby enhancing a photoelectric performance of the epitaxial structure 20.

Referring to FIG. 2 in conjunction with FIG. 1, FIG. 2 is a schematic bottom view of the first embodiment of the micro light emitting device 1 shown in FIG. 1. In FIG. 2, the first semiconductor layer 21 serves as the P-type semiconductor layer of the epitaxial structure 20. The conductive layer 30 may be a metal electrode and serve as a connection electrode for the first semiconductor layer 21. Namely, the conductive layer 30 has the function of a first electrode. The conductive layer 30 may be a dot-shaped electrode, which can achieve directional emission (i.e., narrow-angle illumination). When the conductive layer 30 is the metal electrode, compared with a conventional ITO electrode, the micro light emitting device 1 of the disclosure has a lower forward voltage (VF) and can be widely utilized in low-voltage applications.

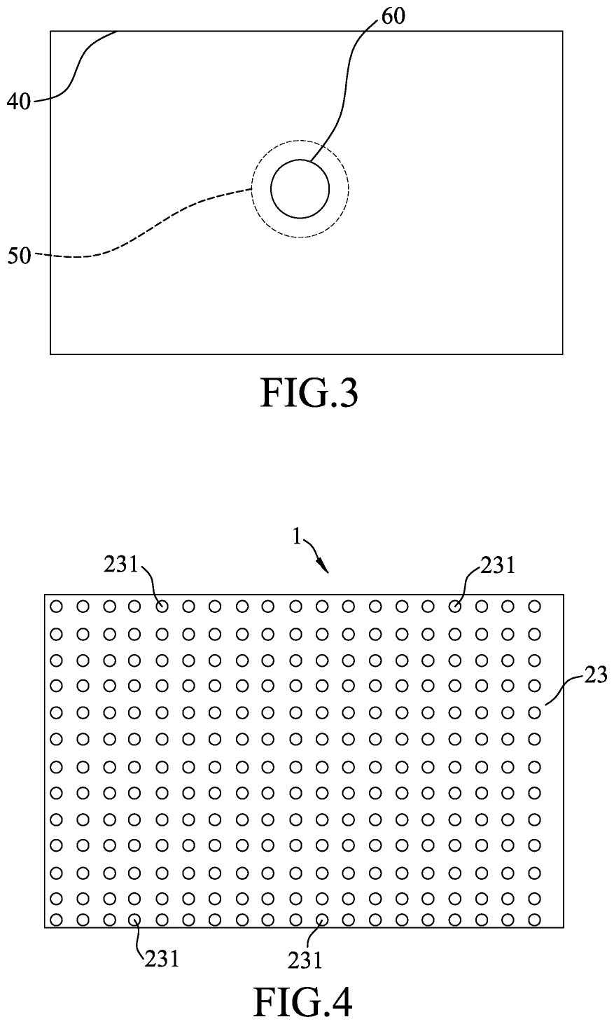

Referring to FIG. 3 in conjunction with FIG. 1, FIG. 3 is a schematic top view of the first embodiment of the micro light emitting device 1 shown in FIG. 1. In FIG. 3, the second semiconductor layer 23 serves as the N-type semiconductor layer of the epitaxial structure 20. The transparent conductive layer 60 may serve as a connection electrode for the second semiconductor layer 23. Namely, the transparent conductive layer 60 has the function of a second electrode. In an exemplary embodiment as shown in FIG. 3, the transparent conductive layer 60 is ITO having good electrical conductivity and light transmittance. The second insulating layer 50 is made of silicon dioxide (SiO₂), and the first insulating layer 40 is a laminated structure of SiO₂ or a single-layer structure of SiO₂. The transparent conductive layer 60 may be a dot-shaped electrode, which can achieve directional emission (i.e., narrow-angle illumination). In this case, the transparent conductive layer 60 is completely attached to the epitaxial structure 20 (i.e., the second surface 20b in FIG. 1), which can reduce adhesion between the transparent conductive layer 60 and the epitaxial structure 20, so as to achieve improved current spreading.

The micro light emitting device 1 has a shortest side not greater than 20 μm and has a longest side not greater than 200 μm. In certain embodiments, the shortest side is not greater than 20 μm, and the longest side is not greater than 20 μm. When a micro light emitting device has a shortest side greater than 20 μm, a lateral current spreading effect of the conductive layer 30 (used as an electrode) is smaller than that of the conventional ITO electrode or the composite electrode having ITO and metal, and a contact area between the electrode and the epitaxial structure is relatively large. Thus, the ITO electrode or the composite electrode having ITO and metal is utilized as the electrode of the micro light emitting device, thereby facilitating the lateral current spreading effect within the epitaxial structure. However, in the micro light emitting device 1 having the shortest side less than 20 μm, a contact area between the electrode and the epitaxial structure 20 is relatively small. Thus, the conductive layer 30 is utilized as the electrode of the micro light emitting device 1, thereby providing enough lateral current spreading effect within the epitaxial structure 20.

In the case where the conductive layer 30 and the transparent conductive layer 60 are the dot-shaped electrodes for the first semiconductor layer 21 and the second semiconductor layer 23, each of the dot-shaped electrodes has a width ranging from 0.5 μm to 8 μm, and may be completely attached to the epitaxial structure 20. As shown in FIG. 2 and FIG. 3, the conductive layer 30 may serve as the first electrode and has a circular cross-section, which has a diameter ranging from 0.5 μm to 8 μm. The transparent conductive layer 60 has a circular cross-section, which has a diameter ranging from 0.5 μm to 8 μm. In some embodiments, the micro light emitting device 1 has a dimension of 5 μm×5 μm, and each of the dot-shaped electrodes (i.e., the conductive layer 30 and the transparent conductive layer 60) for the first semiconductor layer 21 and the second semiconductor layer 23 has a width ranging from 0.5 μm to 3 μm. In certain embodiments, the micro light emitting device 1 has a dimension of 10 μm×10 μm, and each of the dot-shaped electrodes for the first semiconductor layer 21 and the second semiconductor layer 23 has a width ranging from 5 μm to 8 μm.

In the first embodiment, the conductive layer 30 may serve as a contact electrode for the first semiconductor layer 21 and contains a metal material, such as Ti, Pd, Au, Cr, Ni, Pt, or combinations thereof. When the micro light emitting device 1 has the shortest side less than 20 μm, an area of the contact electrode for the first semiconductor layer 21 is relatively small. Thus, the conductive layer 30 containing the aforesaid metal material is utilized as the contact electrode for the first semiconductor layer 21, thereby having the relatively strong current spreading effect.

In a practical example, in a micro light emitting device (i.e., SANAN Optoelectronics Co., Ltd., Cat. no. 35BB-H), a current spreading capability of a ST electrode (made of ITO) of the micro light emitting device is 72 μm and a current spreading capability of an RD electrode (made of ITO) of the micro light emitting device is 58 μm. In the micro light emitting device 1, if a surplus value of the current spreading capability of the conductive layer 30 to that of the conventional ITO electrode ranges from 5% to 10%, the current spreading capability of a light emitting region of the epitaxial structure 20 may range from 2.9 μm to 7.2 μm. Furthermore, the first semiconductor layer 21 is mainly connected to a complementary metal-oxide-semiconductor (CMOS) in a substrate 10 (to be described below). When the area of the conductive layer 30 containing the reflective metal is increased, an area of a reflector-like area for the first semiconductor layer 21 may also be increased, so that the luminous efficiency of the micro light emitting device 1 may be enhanced.

Referring back to FIG. 1, in certain embodiments, the micro light emitting device 1 may further include the substrate 10. The first semiconductor layer 21 of the epitaxial structure 20 is connected onto the substrate 10 through a bonding layer 11. The substrate 10 may be a conductive substrate, a driver circuit board, a metal substrate, etc. In certain embodiments, the substrate 10 may be an insulating substrate, such as an aluminum nitride (AlN) substrate. In some embodiments, the bonding layer 11 may be made of a metal material, and the epitaxial structure 20 may be connected onto the substrate 10 through the bonding layer 11 containing the metal material. In some embodiments, the bonding layer 11 may be bonded at least to the conductive layer 30 or the electrode pad 31.

In the micro light emitting device 1 provided in the first embodiment, the conductive layer 30 is used to replace the conventional composite electrode having ITO and metal, which may simplify the manufacturing process of the micro light emitting device 1. The conventional ITO electrode or the composite electrode having ITO and metal has a light absorbing effect and increases a resistance of the micro light emitting device. Therefore, using the conductive layer 30 in its stead may reduce the resistance of the micro light emitting device 1, which facilitates current spreading. In certain embodiments, the conductive layer 30 contains the reflective metal, so that the conductive layer 30 gains reflector-like functionality, which increases light output, and enhances the luminous efficiency and the luminous brightness of the micro light emitting device 1. The first semiconductor layer 21 and the second semiconductor layer 23 are respectively connected to the dot electrodes (i.e., the conductive layer 30 and the transparent conductive layer 60), which may enhance current spreading in areas where the dot electrodes are located.

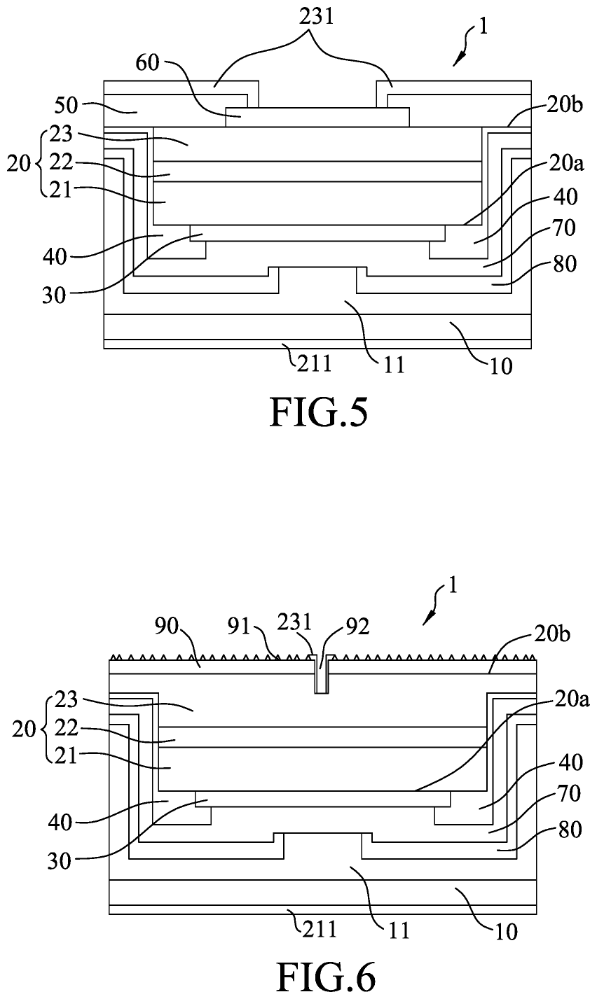

FIG. 5 is a cross-sectional schematic view illustrating a second embodiment of the micro light emitting device 1 according to the disclosure. Similarities between the second embodiment of FIG. 5 and the first embodiment of FIG. 1 are not reiterated herein, but differences are described below.

Referring to FIG. 5 in conjunction with FIG. 1, the micro light emitting device 1 further includes a reflective layer 70 and an insulative blocking layer 80. In certain embodiments, the reflective layer 70 is formed on the first insulating layer 40 and covers at least a part of the first insulating layer 40 and/or at least a part of the surface of the conductive layer 30. In this embodiment, the conductive layer 30 may further include the electrode pad 31 as shown in FIG. 1 (but not shown in FIG. 5). In certain embodiments, the reflective layer 70 has a thickness ranging from 500 Å to 2000 Å, so that the reflective layer 70 forms a film structure on the first insulating layer 40, and is electrically connected to the conductive layer 30. In certain embodiments, the reflective layer 70 contains Al, Ag, Au, or combinations thereof. In some embodiments, the reflective layer 70 may cover a surface of the first insulating layer 40 away from the active layer 22, and a sidewall of the first insulating layer 40, so as to increase light output from a sidewall of the epitaxial structure 20, thereby enhancing the luminous brightness of the micro light emitting device 1.

In certain embodiments, the first insulating layer 40 has a thickness ranging from 2000 Å to 10000 Å. The first insulating layer 40 covers a part of a surface and a sidewall of the conductive layer 30 and the sidewalls of the first semiconductor layer 21, the active layer 22, and the second semiconductor layer 23, so as to offer good insulation and protection for a side portion of the light emitting region of the epitaxial structure 20.

In certain embodiments, the insulative blocking layer 80 is formed on the reflective layer 70 and covers a part of the reflective layer 70. In certain embodiments, the insulative blocking layer 80 has a thickness ranging from 2000 Å to 10000 Å. In some embodiments, the insulative blocking layer 80 contains SiO₂, silicon nitride (SiN), or a combination thereof. As shown in FIG. 5, the insulative blocking layer 80 covers a surface of the reflective layer 70 away from the active layer 22 and a sidewall of the reflective layer 70, so as to offer an effective coverage and an insulation protection for the reflective layer 70, thereby ensuring that the epitaxial structure 20 has good luminous performance.

In certain embodiments, the bonding layer 11 is disposed on the insulative blocking layer 80, and the epitaxial structure 20 may be connected onto the substrate 10 through the bonding layer 11. The bonding layer 11 may contain Ti, Ni, Sn, or combinations thereof. The bonding layer 11 may have a single-layer structure or a laminated structure. The bonding layer 11 may be designed to have an appropriate material and thickness based on various demands of the micro light emitting device 1. In some embodiments, a first electrode 211 may be disposed on a surface of the substrate 10 away from the epitaxial structure 20. The first electrode 211 may be electrically connected to the first semiconductor layer 21 of the epitaxial structure 20.

Referring to FIG. 5 again, in certain embodiments, the micro light emitting device 1 may also include the transparent conductive layer 60 and the second insulating layer 50. The transparent conductive layer 60 is formed on the surface of the second semiconductor layer 23 away from the active layer 22, and is electrically connected to the second semiconductor layer 23. The transparent conductive layer 60 covers a part of the surface of the second semiconductor layer 23 away from the active layer 22 and has a thickness ranging from 120 Å to 1100 Å, so as to ensure that the surface of the second semiconductor layer 23 away from the active layer 22 has good current spreading and light transmittance. The second insulating layer 50 is formed on the transparent conductive layer 60, covers another part of the surface of the second semiconductor layer 23 away from the active layer 22, and exposes a part of the transparent conductive layer 60. The second insulating layer 50 has a thickness ranging from 200 Å to 4000 Å, so as to offer an effective insulation protection for the transparent conductive layer 60 and the another part of the surface of the second semiconductor layer 23 (i.e., the second surface 20b of the epitaxial structure 20 in FIG. 5), thereby ensuring that the second semiconductor layer 23 of the epitaxial structure 20 has good photoelectric performance.

In certain embodiments, the micro light emitting device 1 may have a second electrode 231 that is disposed on the second insulating layer 50. The second electrode 231 covers a surface of the second insulating layer 50 and a part of the transparent conductive layer 60, and exposes a part of the transparent conductive layer 60. In an exemplary embodiment as shown in FIG. 5, the second electrode 231 may serve as a common electrode of the micro light emitting device 1. In some embodiments, the micro light emitting device 1 may include a plurality of transparent conductive layers 60 each of which may be partly exposed from the second electrode 231.

The micro light emitting device 1 provided in the second embodiment is a vertical type micro light emitting device. The first insulating layer 40 covers and protects the sidewalls of the first semiconductor layer 21, the active layer 22, and the second semiconductor layer 23 of the epitaxial structure 20 while the reflective layer 70 and the insulative blocking layer 80 also cover the sidewalls of the first semiconductor layer 21, the active layer 22, and the second semiconductor layer 23. The first insulating layer 40, the reflective layer 70, and the insulative blocking layer 80 form an approximately U-shaped reflective surface, thereby allowing the micro light emitting device 1 to achieve a directional emission (i.e., narrow-angle illumination), reduce light scattering, and enhance the luminous brightness.

FIG. 6 is a cross-sectional schematic view illustrating a third embodiment of the micro light emitting device 1 according to the disclosure. Similarities between the third embodiment of FIG. 6 and the second embodiment of FIG. 5 are not reiterated herein, but differences are described below.

Referring to FIG. 6, the micro light emitting device 1 further includes a roughening layer 91. The roughening layer 91 is disposed on the second semiconductor layer 23 away from the active layer 22, so as to increase the amount of emitted light rays from the second semiconductor layer 23, thereby enhancing a brightness of light emitted from the epitaxial structure 20. The roughening layer 91 may have various shapes and structures, so as to increase roughness of the surface of the second semiconductor layer 23 away from the active layer 22. In an exemplary embodiment as shown in FIG. 6, a profile of a cross-section of the roughening layer 91 features a serrated shape.

In certain embodiments, the micro light emitting device 1 further includes an undoped layer 90. The undoped layer 90 may be directly disposed on the second semiconductor layer 23 away from the active layer 22. In the exemplary embodiment as shown in FIG. 6, the undoped layer 90 is an undoped gallium nitride (GaN) layer. The roughening layer 91 may be disposed on the undoped layer 90 away from the second semiconductor layer 23, thereby enhancing the brightness of light emitted from the epitaxial structure 20.

In this embodiment, the second semiconductor layer 23 of the micro light emitting device 1 is formed with a recess 92 that is defined by a recess-defining wall and that extends inwardly from the surface of the second semiconductor layer 23 opposite to the active layer 22 to expose a part of the second semiconductor layer 23. The recess 92 may have a regular shape or an irregular shape, such as a hole shape, a groove shape, an arc shape, etc. In other embodiments, the second semiconductor layer 23 may be formed with at least one recess 92. When the second semiconductor layer 23 is formed with one recess 92, the recess 92 may be formed at the center of the surface of the second semiconductor layer 23 opposite to the active layer 22 and may have a depth ranging from 0.5 μm to 3 μm. The recess 92 has an opening on the surface of the second semiconductor layer 23 and the opening occupies 5% to 80% of an area of the surface of the second semiconductor layer 23. In certain embodiments, the second semiconductor layer 23 is formed with a plurality of recesses 92, the recesses 92 may be evenly distributed or unevenly distributed. For example, the second semiconductor layer 23 has a central region and a peripheral region surrounding the central region. Distribution density of the recesses 92 at the central region is greater than that at the peripheral region. The distribution density of the recesses 92 may be decreased along a direction from the central region to the peripheral region. At least one of the recesses 92 at the peripheral region may extend into the first insulating layer 40 to expose the first insulating layer 40.

The recess 92 may have varying depths. The cross-section of the recess 92 may have various shapes. In an exemplary embodiment, the opening of the recess 92 has a circular cross-section. In certain embodiments, the second electrode 231 of the micro light emitting device 1 is disposed in the recess 92 and covers a part of the recess-defining wall. The second electrode 231 may serve as a common electrode of the micro light emitting device 1.

In certain embodiments, the second semiconductor layer 23 is formed with a plurality of the recesses 92, and the second electrode 231 or a transparent conductive layer (e.g., the transparent conductive layer 60) is disposed on the recess 92 and covers the part of the recess-defining wall. In some embodiments, the transparent conductive layer may contain ITO. The recess 92 may serve as a current injection point for the second electrode 231 or the transparent conductive layer, injecting current into the light emitting region of the epitaxial structure 20. In certain embodiments, the second electrode 231 may be a transparent structure or a non-transparent structure. In certain embodiments, the second electrode 231 may have reflective function or may not have reflective function. In certain embodiments, the second electrode 231 may be made of a metal material. In an exemplary embodiment, the second electrode 231 contains cadmium (Cd).

In the micro light emitting device 1 provided in the third embodiment, the recess 92 may serve as the current injection point. Due to the small size of the micro light emitting device 1, limitations in an epitaxial uniformity of the epitaxial structure 20 are amplified. In the third embodiment, the micro light emitting device 1 may include a plurality of the recesses 92. By virtue of the plurality of the recesses 92, the current may be injected into the second semiconductor layer 23 through an optimal injection point or through multiple injection points, thereby reducing the forward voltage (VF) of the micro light emitting device 1.

FIG. 4 is a schematic top view illustrating a distribution manner of the second electrodes. As shown in FIG. 4, any one of the aforesaid embodiments of the micro light emitting device 1 may include a plurality of the second electrodes 231 which are distributed on the second semiconductor layer 23 in a checkerboard pattern. In some embodiments, each of the second electrodes 231 may have a dot shape.

In order to achieve at least one of the advantages thereof or other advantages, an exemplary embodiment of the disclosure provides a micro light emitting apparatus. The micro light emitting apparatus includes at least two micro light emitting devices 1 described in any of the aforesaid embodiments of the disclosure. A distance between two adjacent ones of the at least two micro light emitting devices 1 is 2 μm and the at least two micro light emitting devices 1 are electrically connected to each other. When the micro light emitting apparatus is a micro display, an optical crosstalk of the micro light emitting devices 1 may be reduced or prevented, thereby enhancing overall photoelectric performance of the micro light emitting apparatus.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A micro light emitting device, comprising:
an epitaxial structure having a first surface and a second surface opposite to said first surface, and including a first semiconductor layer, an active layer and a second semiconductor layer that are arranged in such order in a direction from said first surface to said second surface;
a conductive layer formed on a surface of said first semiconductor layer away from said active layer; and
a first insulating layer formed on said surface of said first semiconductor layer away from said active layer, and exposing at least a part of said conductive layer.

2. The micro light emitting device as claimed in claim 1, wherein said conductive layer has a thickness ranging from 50 Å to 1000 Å, and contains titanium (Ti), palladium (Pd), gold (Au), chromium (Cr), nickel (Ni), platinum (Pt), or combinations thereof.

3. The micro light emitting device as claimed in claim 1, wherein said conductive layer contains a reflective metal.

4. The micro light emitting device as claimed in claim 1, further comprising
a second insulating layer formed on a surface of said second semiconductor layer away from said active layer, and exposing a part of said second semiconductor layer, and
a transparent conductive layer formed on said second insulating layer, and electrically connected to said second semiconductor layer.

5. The micro light emitting device as claimed in claim 4, wherein said second insulating layer has a thickness ranging from 0.1 Å to 4000 Å, and said transparent conductive layer has a thickness ranging from 0.1 Å to 1100 Å.

6. The micro light emitting device as claimed in claim 1, wherein said micro light emitting device has a shortest side not greater than 20 μm and has a longest side not greater than 20 μm or 200 μm.

7. The micro light emitting device as claimed in claim 1, wherein said conductive layer is a dot-shaped electrode which has a width ranging from 0.5 μm to 8 μm, and which is completely attached to said epitaxial structure.

8. The micro light emitting device as claimed in claim 4, wherein said transparent conductive layer is a dot-shaped electrode which has a width ranging from 0.5 μm to 8 μm, and which is completely attached to said epitaxial structure.

9. The micro light emitting device as claimed in claim 1, further comprising
a reflective layer formed on said first insulating layer and covering at least one of said first insulating layer and said conductive layer, and
an insulative blocking layer formed on said reflective layer and covering a part of said reflective layer.

10. The micro light emitting device as claimed in claim 9, wherein said reflective layer has a thickness ranging from 500 Å to 2000 Å, and contains aluminum (Al), silver (Ag), gold (Au), or combinations thereof.

11. The micro light emitting device as claimed in claim 9, wherein said insulative blocking layer has a thickness ranging from 2000 Å to 10000 Å, and contains silicon dioxide (SiO₂), silicon nitride (SiN), or a combination thereof.

12. The micro light emitting device as claimed in claim 9, wherein said first insulating layer has a thickness ranging from 2000 Å to 10000 Å.

13. The micro light emitting device as claimed in claim 9, further comprising
a transparent conductive layer formed on a surface of said second semiconductor layer away from said active layer, and electrically connected to said second semiconductor layer, and
a second insulating layer formed on said transparent conductive layer, covering a part of said second semiconductor layer away from said active layer, and exposing a part of said transparent conductive layer.

14. The micro light emitting device as claimed in claim 13, wherein said second insulating layer has a thickness ranging from 200 Å to 4000 Å, and said transparent conductive layer has a thickness ranging from 120 Å to 1100 Å.

15. The micro light emitting device as claimed in claim 1, wherein
said second semiconductor layer is formed with a recess that is defined by a recess-defining wall and that extends inwardly from a surface of said second semiconductor layer opposite to said active layer to expose a part of said second semiconductor layer, and
said micro light emitting device further includes a second electrode that covers a part of the recess-defining wall.

16. The micro light emitting device as claimed in claim 9, wherein
said second semiconductor layer is formed with a recess that is defined by a recess-defining wall and that extends inwardly from a surface of said second semiconductor layer opposite to said active layer to expose a part of said second semiconductor layer, and
said micro light emitting device further includes a second electrode that covers a part of the recess-defining wall.

17. The micro light emitting device as claimed in claim 15, wherein said recess has a depth ranging from 0.5 μm to 3 μm, and has an opening at said surface of said second semiconductor layer, said opening occupying 5% to 80% of an area of said surface of said second semiconductor layer.

18. The micro light emitting device as claimed in claim 16, wherein said recess has a depth ranging from 0.5 μm to 3 μm, and has an opening at said surface of said second semiconductor layer, said opening occupying 5% to 80% of an area of said surface of said second semiconductor layer.

19. The micro light emitting device as claimed in claim 9, further comprising a roughening layer that is disposed on said second semiconductor layer away from said active layer.

20. A micro light emitting apparatus, comprising at least two micro light emitting devices as claimed in claim 1, wherein said at least two micro light emitting devices are electrically connected to each other, and a distance between two adjacent ones of said at least two micro light emitting devices is 2 μm.
